(19) United States
(12) Patent Application Publication
(10) Pub. No.: US 2004/0139196 A1
(43) Pub. Date: Jul. 15, 2004

(54) System and method for releasing device reservations

(75) Inventors: Charles P. Butler, Round Rock, TX (US); Richard K. Golasky, Round Rock, TX (US)

Correspondence Address: Roger J. Fulghum, Baker Botts L.L.P., One Shell Plaza, 910 Louisiana Street, Houston, TX, 77002-4995, US

(73) Assignee: DELL PRODUCTS L.P.

(21) Appl. No.: 10/339,212

(22) Filed: Jan. 9, 2003

(51) Int. Cl. G06F 15/173; H03K 19/003; H04B 1/74; H04L 1/22; G06F 17/30

(52) U.S. Cl. 709/225; 714/4; 707/10

(57) ABSTRACT

A method and system for releasing a reservation held by a host on a target device is disclosed. The method includes determining if a reservation held by a host on a target device is releasable, and if so releasing that reservation upon failure of the host. The method may be used in any computer or information handling system.

### TECHNICAL FIELD

This invention relates, in general, to information handling systems, and, more particularly, to an information handling system that uses a releasable reservation protocol for obtaining access to a device.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Many information handling systems include multiple hosts, each host having the capability to access system resources. For some applications, only one host may have access to a specific system resource at one time. Typically, this unique access is granted through a reservation/release system, whereby a host reserves a resource for its exclusive use and then releases that resource when it has performed its operation. Problems arise, however, when a host fails before releasing its reservation of a system resource because any additional hosts cannot access that system resource due to the exclusive reservation of that resource by the failed host. Until the reservation held by the failed host is cleared, that system resource may be unavailable for further use.

SCSI reservations (non third party reservations) may be cleared with a hard reset of the device or by cycling power to the device. Both methods are extremely inconvenient because these processes are not automated and both require human intervention to clear the condition. For example, no automated mechanisms exist to clear SCSI reservations on tape devices. Therefore, tape cartridges may become stuck in tape drives following a host failure. Furthermore, a delay may occur due to clearing any reservations held by a failed host. Finally, the user may be required to manually eject the tape cartridge from the tape drive. Therefore, providing an information handling system with the capability to automatically release reservations held by a failed host would increase the efficiency of such a system.

### SUMMARY

In accordance with the present disclosure, one implementation of a method to release a reservation held by a first host on a target device in a computer system includes determining if the reservation held by the first host on the target device is releasable, determining if the first host has failed, releasing the reservation held by the first host on the target device and reserving the target device to the second host. In accordance with the present disclosure, one implementation of a method to release a reservation held by a first host on a target device in an information handling system includes determining if the reservation held by the first host on the target device is releasable, determining if the first host has failed, releasing the reservation held by the first host on the target device and reserving the target device to the second host. The information handling system may include a memory element unit and a processing unit.

One technical advantage of the method to release a reservation of a device is the automatic detection of LUN reset capable devices. Identification of LUN reset capable devices is important when the disclosed method is used in systems that include devices whose reservations are capable of being released by a host that did not perform the reservation.

Another technical advantage of the method to release a reservation of a device is an automatic LUN reset process through the use of LUN RELEASE that resets a target device while clearing any held SCSI reservations. By minimizing the amount of required user intervention, the computer system operates more efficiently. Another technical advantage of the method to release a reservation of a device is to improve the user experience in Microsoft Cluster Services (MSCS) environments. Because the disclosed method provides an automatic method to release reservations held by a failed host, no user action is required for continued system operation following a failed host that holds a reservation to a target device.

Another technical advantage of the method to release a reservation of a device is to proliferate devices that are cluster aware. This disclosed method can be inserted as a module in, and thus use the features of, a particular cluster environment.

Other technical advantages will be apparent to those of ordinary skill in the art in view of the following specification, claims, and drawings.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 is a system diagram of multiple hosts accessing one or more SCSI devices through an appliance;

FIG. 2 is a flow diagram of one-implementation of the disclosed method to release reservations held on a target device;

FIG. 3A is a flow diagram resulting when Host A holds a reservation to devices A and B;

FIG. 3B is a flow diagram before LUN RELEASE showing the failure of Host A and the transfer of control to Host B;

FIG. 3C is a flow diagram after LUN RELEASE showing the transfer of control to Host B and the reservations of target devices A and B to Host B; and

FIG. 4 is a flow diagram showing the method of identifying of a device is capable of releasing a reservation held by a host.

### DETAILED DESCRIPTION

For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

The disclosed method for releasing a reservation of a target device permits a host to automatically clear SCSI reservations on a target device notwithstanding that another host may hold a SCSI reservation on the target device. When a host has failed and lacks the ability to access the target device it to which it holds the SCSI reservation, one implementation of a method for releasing a reservation of a target device provides a second host with the capability to release the reservations on that same target device. This second host may access and clear the SCSI reservation on the target device though the first host holds a SCSI reservation on the target device.

The disclosed method for releasing a reservation of a target device may apply to any system permitting access to a target device including devices in a Microsoft Cluster System (MSCS) cluster environment. The disclosed method for releasing a reservation of a target device may be used in systems in which servers rely on SCSI reserve and release for exclusive access to a device. In one implementation, a cluster environment may include two computers, such that the two computers operate as a single computer. Each computer in a MSCS environment may be referred to as a node. In a two computer (two node) cluster system, one node may service all requests, and consequently that node is the active node. The resources of a node in a MSCS, e.g., the nodes that are not active, environment include the requests to that node. The remaining nodes in a MSCS can be in a passive mode. However, if the active node fails, then the resources may shift to a failover node. This transferring of resources is a transparent process from the viewpoint of a computer user in the MSCS environment.

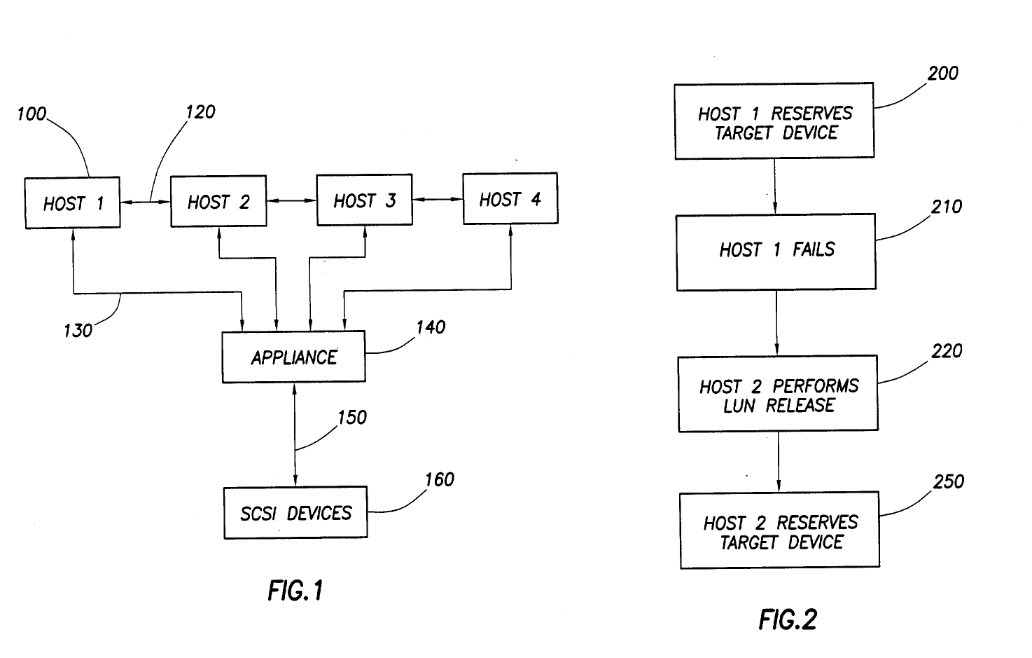

FIG. 1 is a diagram of a cluster system that includes four hosts or nodes 100. Interfaces 120 couples the four nodes 100 of the cluster environment. If one of the four hosts 120 becomes the controlling node, that host can access a SCSI device 160, for which no reservation is held, through appliance 140. Interface 130 couples the active node to the appliance, and interface 150 couples the appliance to the SCSI devices. Following failure of the active node, the disclosed method of releasing a reservation held by a host will permit the new active node to access any SCSI device reserved by the failed host.

The nodes of a MSCS system may use the SCSI protocol when accessing its resources. Utilizing the reserve and release functionality of the SCSI protocol, a node may obtain exclusive access to a device. When a node becomes active, the MSCS environment reserves the resources required by the active node. The remaining nodes in the system cannot access the resources or devices that have been reserved to the active node. Although a resource may be shared by two different nodes or hosts, the SCSI protocol permits only one node to access the shared resource at one time. The reserve/release commands are a protection mechanism to prevent mote than one host from accessing a resource at one time. During normal operation, the host that has reserved a resource must release that resource before a second host may access that resource. However, if the active node fails, the MSCS system will detect that failure and shift the resources and ownership of devices to another node. However, this new active node cannot access resources that have been previously reserved by the failed node, unless the reservations held by the prior active node are released. In the case of tape backup devices, if a host dies while holding a reservation on a tape device, the failover node may require access to the tape device, but because the first host never released the SCSI reservation, the second host would not have access to the tape device, unless a method for the automated mechanism used in this invention is utilized.

The disclosed method for releasing reservations held on a releasable device facilitates automatic transfer of control to another node following failure of an active node. The method clears the reservation and any outstanding commands the device may be executing during the time that the failure occurs and a node becomes active following node failure. Thus, because the newly active node may gain access to system resources, even those that were previously reserved by the failed node, the transfer of resources from one node to another is automated.

One implementation of a method for releasing reservations of a releasable device includes two steps. First, target devices that are capable of responding to a LUN RELEASE command are identified. Second, the devices are reset and SCSI reservations are cleared automatically. The automated LUN RELEASE mechanism may be generated each time by the cluster nodes during a cluster failover. Following cluster failover, resources and ownership are transferred from one node to another. In general, the methods disclosed herein provides a safe and automated mechanism for clearing a SCSI reservation. The LUN RELEASE command provides a way to clear any SCSI reservation held by a host bus adapter (HBA) on a LUN by LUN basis. The command will also clear out any outstanding I/O to the specified LUN.

FIG. 2 illustrates one implementation of a method to transfer control of a releasable target device following failure of a host. As shown in FIG. 2, host 1 first reserves a target device (block 200). Host 1 subsequently fails as shown in block 210. Host 2 may then release the reservation of target device by performing a LUN RELEASE as shown in block 220. Finally, following the LUN RELEASE host 2 reserves the target device as shown in block 250. When host 2 resumes its operations following failover, the reservations held by host 1 are automatically released and cleared.

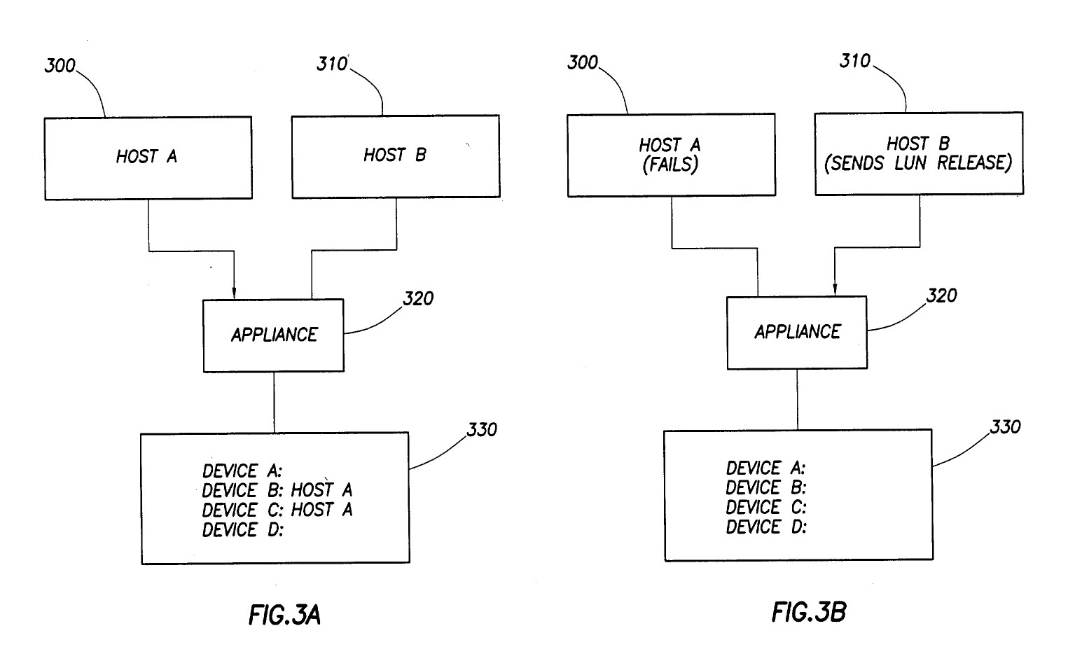

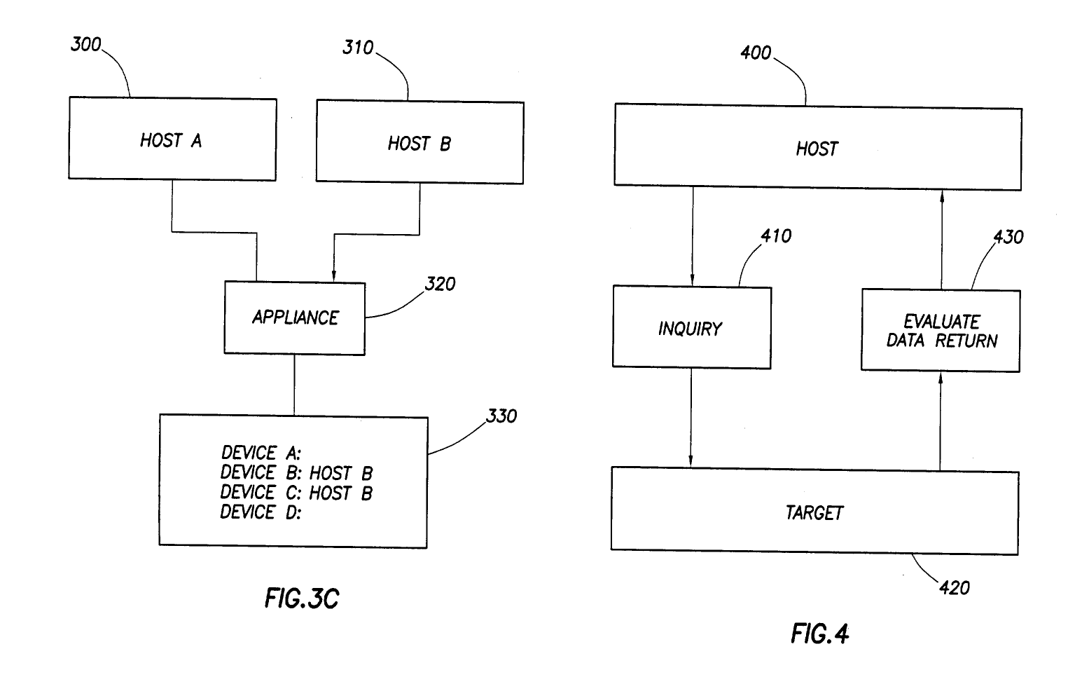

An implementation of the LUN RELEASE capability is shown in FIG. 3. In FIG. 3A, host A has, through appliance 320, gained control of devices B and C as shown in block 330. Devices A, B, C and D in block 330 may be any device such as disk drives, tape drives, CD ROM drives, expansion cards, or any other input-output device. As shown in block 320, the appliance may be a process that connects the hosts A and B to the SCSI devices 330. The appliance may appear to the host as connections of inputs and outputs. During the period that host A reserves control of SCSI devices B and C, host B, as shown in 310, cannot access devices B and C. Thus, when host A fails as shown in FIG. 3B, no host will have control of devices B and C as shown in block 330, however, the SCSI reservations on devices B and C are still held by the failed Host A. Host B for example cannot control devices B and C shown in 330 because host A has reserved control of those devices. However, when host B sends a LUN RELEASE through appliance 320 to the devices, host B may reserve and thus gain access to the devices of 330 (FIG. 3C). Here host B block 310, through appliance 320, accesses or maintains control of devices B and C in block 330.

Releasing of a reservation of a target device may occur by performing a LUN RELEASE as shown in 220. The LUN RELEASE may be executed in two steps. The first step is to identify if the target device is LUN RELEASE capable, and the second step is to perform the LUN RELEASE function.

FIG. 4 illustrates one implementation of executing the inquiry step. As shown in FIG. 4, the host 400 first sends an inquiry illustrated by block 410 to the target device. An inquiry page code (0xDF) provides the identification that the target device is LUN releasable. The 0xDF page code responds with the contents of “$DELL-CLUSTER”. By receiving this particular data response to the inquiry, the host determines that the target device is LUN RELEASE capable. The inquiry command (block 410) may be implemented as a SCSI command. The inquiry command inquires into the page code of the device and returns a specific string if the device is LUN RELEASE capable. In one implementation, the returned string may be $DELL-CLUSTER. The target (block 420) responds to the inquiry command 410 by sending the contents of the $DELL-CLUSTER, if it exists, to the host. Thus, in response to the inquiry command, the target may respond with the appropriate inquiry data if it supports the LUN RELEASE command. Otherwise, the target will respond with a data response indicating that the LUN RELEASE command is not supported such as a response of invalid CDB. In another implementation of releasing a reservation of a target device or identifying a LUN release capable device, an appliance may receive the inquiry command or LUN reset command and respond on behalf of the target. For example, an appliance may be a bridge between the target device and the communication protocol itself. The host evaluates the response (block 430) to determine if the target is LUN RELEASE capable.

The second step of one implementation of releasing a reservation of a target device is to perform the LUN RELEASE function itself. The use of a specific command descriptive block (CDB), LUN RELEASE, automatically clears the SCSI reservations held by target devices. A CDB is synonymous with a SCSI command. In particular, the SCSI command is LUN RELEASE. The LUN RELEASE command will clear the SCSI reservations in a target device as well as clearing any pending commands and flushing buffers. In MSCS cluster failover scenarios the LUN RELEASE command typically does not require human intervention to clear SCSI reservation. The LUN RELEASE mechanism eliminates steps in the failover process and provides a seamless transition for the failover node expected in the MSCS failover situation.

Following execution of LUN RELEASE, responses are received by the active node to identify whether the release was successful. The responses may identify any error condition that may have occurred. In one implementation, the LUN RELEASE command may return GOOD status after the target successfully clears the outstanding I/O and reservations. Additionally, the target may return GOOD status in situations for which no reservation and/or no I/O is pending to the target. In a fibre channel environment, the target or appliance interface (block 430) may return a BA_RJT to any ABTS from a host that has had I/O cleared out by the LUN RELEASE command. If no reservation is held and I/O is pending to the target, the target may return a CHECK CONDITION with Sense Key 09h, additional sense code (ASC) 04, and additional sense code qualifier (ASCQ) 07, indicating Logical Unit not Ready, Operating in Progress. Sense keys may be defined by SCSI or user specific protocols. If the target or appliance interface cannot successfully complete the LUN RELEASE command, the target may return the appropriate Sense Key, ASC, and ASCQ.

Host applications may determine if a device supports the LUN release command. This function may be accomplished through the user of a vendor specific inquiry page. In the case that a Fiber Channel Bridge supports the LUN RELEASE command, the Fiber Channel Bridge may handle the requests and responses for this specific page code since a device connected to the Fiber Channel Bridge will have no knowledge of the LUN RELEASE capability. This may be performed for each device connected to the SCSI Ports of the Fiber Channel Bridge.

The LUN reset capability and the use of the LUN RELEASE CDB can be extended to other storage devices. In addition, the LUN reset mechanism can be used in other topologies that rely on SCSI reservations for device access such as storage area networks (SAN). The current implementation has primarily focused on clusters but may be used in larger topologies. Moreover, the LUN RELEASE operation may be performed one or more times, including each time a node becomes active.

The disclosed method is not to be limited to SCSI devices, but may be applied to other storage devices such as storage area networks (SANs). The method may also be applied to other shared devices such as a shared CD ROM drive or a shared DVD drive. Moreover, the disclosed method may be applied to systems that use ATA, fiber channel, or Fire Wire protocols.

Although the present disclosure has been described in detail, it should be understood that various changes, substitutions, and alterations can be made hereto without departing from the spirit and the scope of the invention as defined by the appended claims.

What is claimed is:

1. A method for releasing a reservation of a target device in a computer system, the computer system including a first and second host, the first and second hosts are communicatively coupled to the target device, the first host reserving the target device, the method comprising:
determining if the reservation held by the first host on the target device is releasable;
determining if the first host has failed;
releasing the reservation held by the first host on the target device; and
reserving the target device to the second host.

2. The method of claim 1, wherein the target device is reserved to the second host if the reservation held by the first host on the target device was successfully released.

3. The method of claim 1, wherein the target device is compatible with a small computer systems interface (SCSI) protocol or fiber channel protocol.

4. The method of claim 1, wherein the target device is a storage area network (SAN).

5. The method of claim 1, wherein the target device is a shared device.

6. The method of claim 5, wherein the shared device is a tape backup device, CD ROM drive, DVD drive, hard disk drive, or floppy disk drive.

7. The method of claim 1, wherein determining if the reservation held by the first host on the target device is releasable further comprises:
interrogating the target device; and
sending a signal to the second host, if the target device is releasable.

8. The method of claim 1, wherein the computer system determines if the first host has failed.

9. The method of claim 1, wherein the second host determines if the first host has failed.

10. The method of claim 1, wherein the first and second hosts are communicatively coupled to the target device by an appliance.

11. A method for determining if a reservation held by a host on a target device in a computer system is releasable, the computer system including a host communicatively coupled to the target device, the method comprising:
interrogating the target device; and
sending a signal to the host, if the target device is releasable.

12. A method for releasing a reservation of a target device in an information handling system, the information handling system including at least one memory, a processing unit, a first and second host, the first and second hosts are communicatively coupled to the target device, the first host reserving the target device, the method comprising:
determining if the reservation held by the first host on the target device is releasable;
determining if the first host has failed;
releasing the reservation held by the first host on the target device; and
reserving the target device to the second host.

13. The method of claim 12, wherein the target device is reserved to the second host if the reservation held by the first host on the target device was successfully released.

14. The method of claim 12, wherein the target device is compatible with a small computer systems interface (SCSI) protocol or fiber channel protocol.

15. The method of claim 12, wherein the target device is a storage area network (SAN).

16. The method of claim 12, wherein the target device is a shared device.

17. The method of claim 16, wherein the shared device is a tape backup device, CD ROM drive, DVD drive, hard disk drive, or floppy disk drive.

18. The method of claim 12 wherein determining if the reservation held by the first host on the target device is releasable further comprises:
interrogating the target device; and
sending a signal to the second host, if the target device is releasable.

19. The method of claim 12, wherein the information handling system determines if the first host has failed.

20. The method of claim 12, wherein the second host determines if the first host has failed.

21. The method of claim 12, wherein the first and second hosts are communicatively coupled to the target device by an appliance.

22. An information handling system, comprising:
at least one memory;
a processing unit;
a first host and second host, the first and second hosts are communicatively coupled to a target device, the first host reserving the target device;
wherein
the reservation of the target device is releasable;
the reservation of the target device held by the first host is released if the first host fails; and
the reservation of the target device is reserved to the second host.
